(19) United States
(12) Patent Application Publication
(10) Pub. No.: US 2023/0367927 A1
(43) Pub. Date: Nov. 16, 2023

(54) NON-TRANSITORY COMPUTER READABLE STORAGE MEDIUM STORING OPERATION IMPROVEMENT ASSISTANCE PROGRAM, OPERATION IMPROVEMENT ASSISTANCE DEVICE, AND OPERATION IMPROVEMENT ASSISTANCE METHOD

(71) Applicant: Mitsubishi Electric Corporation, Tokyo (JP)

(72) Inventor: Shota NAKANO, Tokyo (JP)

(73) Assignee: Mitsubishi Electric Corporation, Tokyo (JP)

(21) Appl. No.: 18/031,891

(22) PCT Filed: Mar. 18, 2021
(86) PCT No.: PCT/JP2021/011224

§ 371 Date: Apr. 14, 2023

(51) Int. Cl. G06F 30/20

(52) U.S. Cl. CPC G06F 30/20

(57) ABSTRACT

A non-transitory computer readable storage medium stores an operation improvement assistance program that is a program for causing a computer to function as an operation improvement assistance device that assists improvement of an operation status of a device or improvement of an outcome by operation of the device. The operation improvement assistance program causes a computer to execute process procedures including: predicting output data indicating the operation status or the outcome from input data including each value of a plurality of feature amounts related to operation of the device; extracting a target feature amount whose value is changeable in prediction of the output data, from among the plurality of feature amounts; a step of simulating the predicted output data by changing a value of the target feature amount; and presenting a simulation result of the output data.

### FIELD

The present disclosure relates to an operation improvement assistance program, an operation improvement assistance device, and an operation improvement assistance method for assisting improvement of operation of a device.

### BACKGROUND

For a device operating in a factory or the like, there is known a technique of inputting data regarding the operation of the device to a prediction model and outputting data for evaluating the operation of the device. Patent Literature 1 discloses an evaluation system for learning a prediction model for obtaining an evaluation value, which is output data, from factory measurement data, which is input data, and predicting the evaluation value by using the prediction model, to evaluate operation of a factory. In addition, the evaluation system of Patent Literature 1 receives a change in input data and inputs the changed input data to the prediction model, to simulate the evaluation value in a case where an operation plan is changed.

### CITATION LIST

### Patent Literature

Patent Literature 1: Japanese Patent Application Laid-open No. 2020-140252

### SUMMARY

### Technical Problem

According to the technique of Patent Literature 1, when changing input data, an operator of the evaluation system needs to determine a parameter whose value is to be changed from among parameters included in the input data. In a case of improving operation of a device by the technique of Patent Literature 1, determination of the parameter whose value is to be changed is left to the operator. Therefore, whether or not changing the value of the determined parameter is effective as an improvement measure may depend on ability or experience of the operator. In addition, trial and error may be required to determine the parameter whose value is to be changed. As described above, according to the technique of Patent Literature 1, there has been a problem that it is difficult to consider measures for improving the operation of the device.

The present disclosure has been made in view of the above, and an object is to obtain an operation improvement assistance program for enabling easy consideration of a measure for improvement regarding operation of a device.

### Solution to Problem

In order to solve the above problem and achieve the object, the present disclosure is an operation improvement assistance program for causing a computer to function as an operation improvement assistance device that assists improvement of an operation status of a device or improvement of an outcome by operation of the device. The operation improvement assistance program causing the computer to execute process procedures includes: a step of predicting output data indicating the operation status or the outcome from input data including each value of a plurality of feature amounts related to operation of the device; a step of extracting a target feature amount whose value is changeable in prediction of the output data, from among the plurality of feature amounts; a step of simulating the predicted output data by changing a value of the target feature amount; and a step of presenting a simulation result of the output data.

### Advantageous Effects of Invention

An operation improvement assistance program according to the present disclosure has an effect of enabling easy consideration of a measure for improvement regarding operation of a device.

### BRIEF DESCRIPTION OF DRAWINGS

FIG. 1 is a diagram illustrating a configuration of an operation improvement assistance device according to a first embodiment.

FIG. 2 is a flowchart illustrating an operation procedure in simulating output data obtained by the operation improvement assistance device according to the first embodiment.

FIG. 3 is a flowchart illustrating an operation procedure in using a simulation result obtained by the operation improvement assistance device according to the first embodiment.

FIG. 4 is a view for explaining an input of a target value of output data in the operation improvement assistance device according to the first embodiment.

FIG. 5 is a view for explaining presentation of items of a simulation result and a target feature amount in the operation improvement assistance device according to the first embodiment.

FIG. 6 is a view for explaining selection of a feature amount in the operation improvement assistance device according to the first embodiment.

FIG. 7 is a view for explaining an importance degree acquired in order to select a target feature amount in the operation improvement assistance device according to the first embodiment.

FIG. 8 is a diagram illustrating a configuration example of hardware for implementing the movement improvement assistance device according to the first embodiment.

### DESCRIPTION OF EMBODIMENTS

Hereinafter, an operation improvement assistance program, an operation improvement assistance device, and an operation improvement assistance method according to an embodiment will be described in detail with reference to the drawings.

### First Embodiment

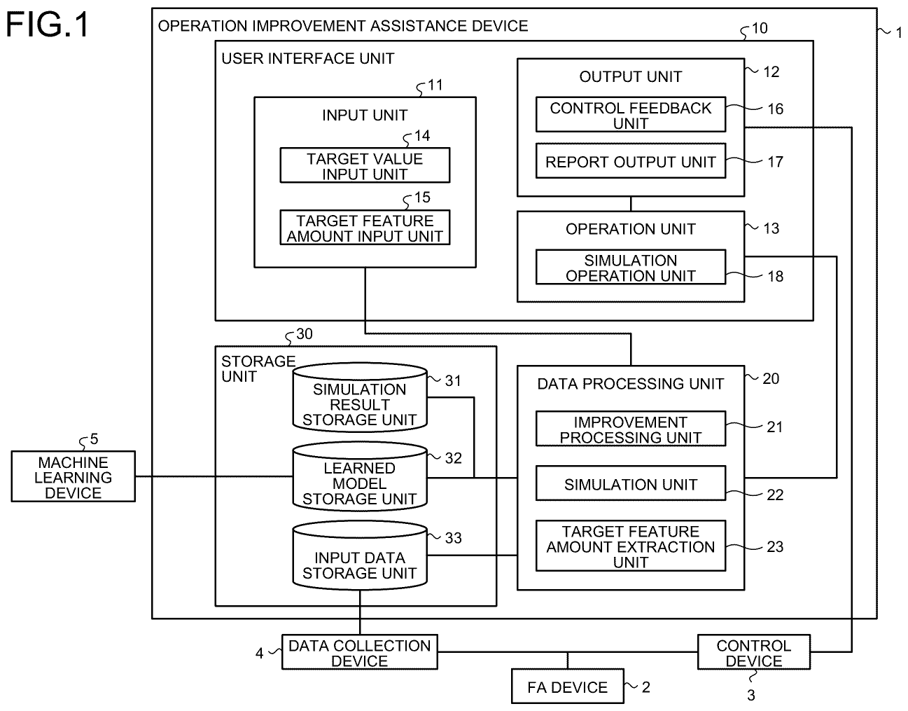

FIG. 1 is a diagram illustrating a configuration of an operation improvement assistance device 1 according to a first embodiment. The operation improvement assistance device 1 assists improvement of an operation status of a device or improvement of an outcome by operation of the device. In the first embodiment, the device is a factory automation (FA) device 2 installed in a factory. FIG. 1 illustrates a functional configuration of the operation improvement assistance device 1, the FA device 2, a control device 3 that controls the FA device 2, a data collection device 4 that collects data regarding the FA device 2, and a machine learning device 5. The FA device 2 is, for example, a processing machine.

In the first embodiment, the operation improvement assistance device 1 assists the FA device 2 or an FA system including the FA device 2, in improving an operation status such as improving productivity, improving the operation status by monitoring for preventive maintenance, and the like. Alternatively, the operation improvement assistance device 1 assists improvement in quality of a product that is an outcome of the operation of the FA device 2 or the FA system. Note that the FA device 2 is not limited to the processing machine, and may be a device other than the processing machine. The use of the operation improvement assistance device 1 described here is given as an example, and the use of the operation improvement assistance device 1 is not limited thereto.

The operation improvement assistance device 1 includes a user interface unit 10, a data processing unit that processes data inputted to the operation improvement assistance device 1, and a storage unit 30 that stores information.

The user interface unit 10 includes: an input unit 11 that receives an input of data from an outside of the operation improvement assistance device 1; an output unit 12 that outputs data to the outside of the operation improvement assistance device 1; and an operation unit 13 that is operated by an operator of the operation improvement assistance device 1. The input unit 11 receives manual input by the operator. Details of the input unit 11, the output unit 12, and the operation unit 13 will be described later.

The data processing unit 20 includes an improvement processing unit 21, a simulation unit 22, and a target feature amount extraction unit 23. The storage unit includes a simulation result storage unit 31, a learned model storage unit 32, and an input data storage unit 33.

The input data storage unit 33 stores input data that is data collected during operation of the FA device 2. The input data includes a parameter representing each of a plurality of feature amounts related to the operation of the device. That is, the input data includes each value of a plurality of feature amounts related to the operation of the device. Specific examples of the feature amount will be described later. The target feature amount extraction unit 23 extracts a target feature amount from among the plurality of feature amounts whose values are included in the input data. The target feature amount is a feature amount to be a target of simulation, and is a feature amount whose value is changeable in prediction of the output data.

The learned model storage unit 32 stores a learned model generated by preliminary machine learning. The simulation unit 22 predicts output data by inputting input data to the learned model. Furthermore, the simulation unit 22 simulates predicted output data by changing a value of the target feature amount. The simulation result storage unit 31 stores a simulation result obtained by the simulation unit 22. The improvement processing unit 21 performs processing for presenting an improvement measure on the basis of a target value of the output data and the simulation result. The improvement processing unit 21 performs processing for presenting, as improvement measures, the simulation result and individual items of the target feature amount that enable to achieve the target value of the output data or obtain output data close to the target value.

The input unit 11 includes: a target value input unit 14 to which a target value of output data is inputted; and a target feature amount input unit 15 to which information on the selected feature amount is inputted when a feature amount to be included in the target feature amount is narrowed down among the plurality of feature amounts by selection of the operator.

The operation unit 13 includes a simulation operation unit 18. The simulation operation unit 18 presents a range of a changeable value of the target feature amount, together with the simulation result and items of the target feature amount presented as the improvement measures. In addition, the simulation operation unit 18 receives an operation of changing the value of the target feature amount in the presented range. The operation improvement assistance device 1 changes a prediction result of output data indicated by the simulation result, by operating the simulation operation unit 18. The simulation operation unit 18 has a function as a presentation unit that presents the simulation result, the item of the target feature amount, and the range of a changeable value of the target feature amount.

The output unit 12 includes a control feedback unit 16 and a report output unit 17. The control feedback unit 16 outputs a feedback value to the control device 3. The feedback value includes a value of a target feature amount corresponding to a simulation result set as the improvement measure. Alternatively, the feedback value includes a value of a target feature amount changed by the operation on the simulation operation unit 18. The report output unit 17 outputs a report summarizing the feedback value and the simulation result, to the outside of the operation improvement assistance device 1.

The data collection device 4 acquires data from the FA device 2, and collects the acquired data. The operation improvement assistance device 1 stores the data collected by the data collection device 4 into the input data storage unit 33.

The machine learning device 5 generates a learned model for predicting output data indicating an operation status of the device or an outcome by the operation of the device, from the input data. The machine learning device 5 generates the learned model by supervised learning or unsupervised learning. The operation improvement assistance device 1 stores the learned model generated by the machine learning device 5 into the learned model storage unit 32.

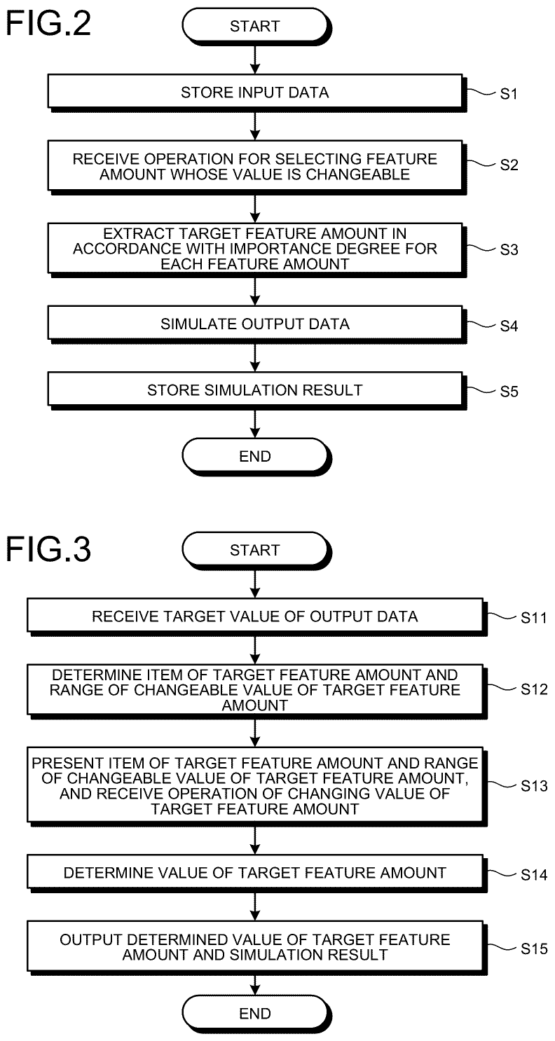

Next, an operation of the operation improvement assistance device 1 in simulating output data on the basis of collected input data will be described. FIG. 2 is a flowchart illustrating an operation procedure in simulating output data by the operation improvement assistance device 1 according to the first embodiment.

The data collection device 4 acquires data from the FA device 2, and collects the acquired data. In step S1, the operation improvement assistance device 1 stores input data collected by the data collection device 4 into the input data storage unit 33.

In step S2, the operation improvement assistance device 1 receives an operation for selecting a feature amount whose value is changeable. Information on the feature amount selected by the operator is inputted to the target feature amount input unit 15. The information on the selected feature amount is transmitted to the target feature amount extraction unit 23.

In step S3, the operation improvement assistance device 1 causes the target feature amount extraction unit 23 to extract a target feature amount, in accordance with an importance degree for each feature amount. The target feature amount extraction unit 23 reads input data from the input data storage unit 33. The target feature amount extraction unit 23 narrows down the feature amount selected by the operator, from a plurality of feature amounts whose values are included in the input data. The target feature amount extraction unit 23 acquires information on an importance degree of each of the narrowed feature amounts, from the learned model in the learned model storage unit 32. The target feature amount extraction unit 23 selects a target feature amount from among the narrowed feature amounts, in accordance with the importance degree of each feature amount. Thus, the target feature amount extraction unit 23 extracts the target feature amount whose value is changeable in prediction of output data, from among the plurality of feature amounts.

In step S4, the operation improvement assistance device 1 simulates output data in the simulation unit 22. The simulation unit 22 acquires information on the target feature amount from the target feature amount extraction unit 23. The simulation unit 22 predicts output data by inputting input data read from the input data storage unit 33, to the learned model read from the learned model storage unit 32. In addition, the simulation unit 22 changes a value of the target feature amount included in the input data, and inputs the input data including the changed value to the learned model. Thus, the simulation unit 22 simulates predicted output data by changing the value of the target feature amount. The simulation unit 22 predicts output data from the input data before changing the value of the target feature amount, and further simulates output data predicted while changing the value of the target feature amount. The value of the target feature amount is changed in a preset range, from the value at the time when the input data is acquired. The simulation unit 22 repeats changing the value in the range and simulating the output data.

In step S5, the operation improvement assistance device 1 stores a simulation result obtained by the simulation unit 22, into the simulation result storage unit 31. By the simulation unit 22 repeating the simulation, simulation results are accumulated in the simulation result storage unit 31. Thus, the operation improvement assistance device 1 ends the processing according to the procedure illustrated in FIG. 2. The simulation result accumulated in the simulation result storage unit 31 is used in searching for a value of the target feature amount that can improve the value of the output data.

The input data includes a value of a feature amount that can be adjusted by the operator and a value of a feature amount that cannot be adjusted by the operator. Examples of the feature amount that can be adjusted by the operator include, for example, a control parameter and the like. Examples of the feature amount that cannot be adjusted by the operator include, for example, time, a material of a workpiece, and the like. When all the feature amounts whose values are included in the input data are set as a target of the simulation, the simulation may require an enormous time and an enormous calculation amount. By the operator narrowing down the feature amounts whose values can be adjusted by the operator, the operation improvement assistance device 1 excludes the feature amounts that cannot be adjusted in improving operation from the simulation target. The operation improvement assistance device 1 can reduce time required for simulation and a calculation amount, and can efficiently perform simulation.

The learned model includes information indicating an importance degree of each feature amount. That is, the importance degree is calculated when the learned model is generated. The importance degree is, for example, a decision tree importance degree, a coefficient in linear regression, a dimension compression contribution rate, or the like. The operation improvement assistance device 1 can perform simulation with emphasis on a feature amount having a high importance degree, by selecting the target feature amount in accordance with the importance degree.

Next, an operation of the operation improvement assistance device 1 in using a simulation result will be described. FIG. 3 is a flowchart illustrating an operation procedure in using a simulation result obtained by the operation improvement assistance device 1 according to the first embodiment.

In step S11, the operation improvement assistance device 1 receives a target value of output data in the target value input unit 14. To the target value input unit 14, the target value is inputted by the operator. The inputted target value is sent to the improvement processing unit 21.

In step S12, the operation improvement assistance device 1 causes the improvement processing unit 21 to determine an item of a target feature amount and a range of a changeable value of the target feature amount. The improvement processing unit 21 reads a simulation result from the simulation result storage unit 31. From among the read simulation results, the improvement processing unit 21 selects a simulation result that enables to achieve the target value of the output data or to obtain output data close to the target value. The improvement processing unit 21 determines the selected simulation result as a simulation result to be presented. In addition, the improvement processing unit 21 determines an item of the target feature amount in the selected simulation result, as an item of the target feature amount to be presented. Further, the improvement processing unit 21 determines a range of a changeable value for each item of the target feature amount. The improvement processing unit 21 sends the determined simulation result, the determined item of the target feature amount, and the value range for each item of the target feature amount to the simulation operation unit 18.

In step S13, the operation improvement assistance device 1 presents the item of the target feature amount and the range of a changeable value of the target feature amount, in the simulation operation unit 18. In addition, the operation improvement assistance device 1 receives an operation of changing the value of the target feature amount in the simulation operation unit 18. The simulation operation unit 18 presents the item of the target feature amount acquired from the improvement processing unit 21, together with the simulation result acquired from the improvement processing unit 21. In addition, the simulation operation unit 18 presents the range of a changeable value of the target feature amount acquired from the improvement processing unit 21. The simulation operation unit 18 changes a prediction result of the output data indicated in the simulation result, in accordance with the operation of changing the value of the target feature amount.

In step S14, the operation improvement assistance device 1 determines a value of the target feature amount, in accordance with an operation by the operator on the simulation operation unit 18. The operator changes the value of the target feature amount with reference to the presented prediction result, to search for a value of the target feature amount that can improve the value of the output data. To improve the value of the output data means to bring the value of the output data close to the target value of the output data. The simulation operation unit 18 sends the determined value of the target feature amount to the output unit 12.

In step S15, the operation improvement assistance device 1 causes the output unit 12 to output the determined value of the target feature amount and the simulation result. The control feedback unit 16 acquires the value of the target feature amount from the simulation operation unit 18, and outputs a feedback value which is the acquired value of the target feature amount. The report output unit 17 acquires the determined value of the target feature amount and the simulation result from the simulation operation unit 18, and outputs a report summarizing the feedback value and the simulation result. Thus, the operation improvement assistance device 1 ends the processing according to the procedure illustrated in FIG. 3.

When determining that the value of the output data can be improved with the simulation result determined by the improvement processing unit 21, the operator determines not to change the value of the target feature amount by operating the simulation operation unit 18. In this case, the operation improvement assistance device 1 adopts, as the improvement measure, the value of the target feature amount as it is corresponding to the simulation result determined by the improvement processing unit 21. The simulation operation unit 18 sends the value of the target feature amount corresponding to the simulation result to the output unit 12.

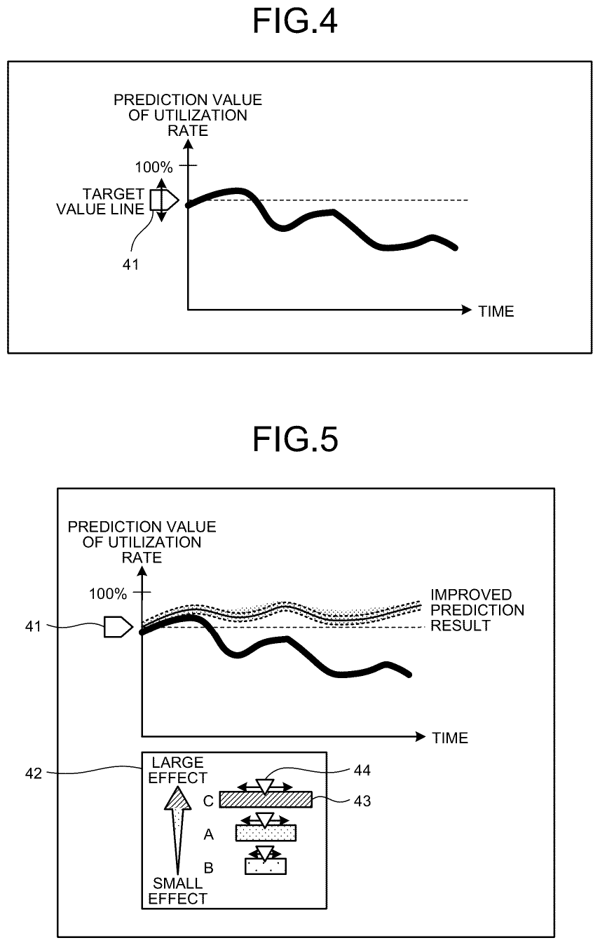

FIG. 4 is a view for explaining an input of a target value of output data in the operation improvement assistance device 1 according to the first embodiment. FIG. 4 illustrates an example of an input screen displayed by a function of the target value input unit 14. A graph illustrated on the input screen represents a simulation result of the output data. In the example illustrated in FIG. 4, the output data is a utilization rate of the FA device 2. A vertical axis of the graph represents a prediction value of the utilization rate of the FA device 2. A horizontal axis of the graph represents time. In this way, the operation improvement assistance device 1 presents the simulation result of the output data by displaying the graph representing a relationship between a value of the output data and time. By the graph indicating a time series of values of the output data, the operator can check a transition of the predicted output data.

The input screen displays a pointer 41 for adjustment of a value of the utilization rate as the target value in the graph. The operator moves the pointer 41 in a direction of the vertical axis by operating a mouse or the like. A broken line of “target value line” in the graph illustrated in FIG. 4 represents a target value selected by the pointer 41. The operator moves the pointer 41 to a position of a value of the utilization rate to be a target value, and then performs an operation for determining the position of the pointer 41 to determine the target value to be inputted to the target value input unit 14. In this manner, the target value is inputted to the target value input unit 14. Note that a display content and an operation method described here are given as an example, and are not limited to these display content and operation method.

FIG. 5 is a view for explaining presentation of a simulation result and items of target feature amounts in the operation improvement assistance device 1 according to the first embodiment. FIG. 5 illustrates an example of an operation screen displayed by a function of the simulation operation unit 18. Similarly to the input screen illustrated in FIG. 4, a graph representing a simulation result of output data is displayed on the operation screen.

In a display area 42 in the operation screen, items of target feature amounts and ranges of changeable values of the target feature amounts are displayed. Each of “A”, “B”, and “C” in the display area 42 in FIG. 5 represents the item of the target feature amount. In FIG. 5, three items of the target feature amount are displayed. In addition, a slide bar 43 illustrated on the right of each item represents a range of a changeable value of the target feature amount. Further, a pointer 44 for change of a value of the target feature amount is attached to each slide bar 43. Note that a display content and an operation method described here are given as an example, and are not limited to these display content and operation method.

“A”, “B”, and “C” are feature amounts extracted by the target feature amount extraction unit 23. In addition, an order of a level of an importance degree of each feature amount is assumed to be the order of “C”, “A”, and “B” from the highest. In the display area 42, the three items of the feature amount are displayed to be aligned from top to bottom in descending order of the importance degree. The importance degree can also be said to be magnitude of an effect of changing the value in the operation improvement measure. “Large effect” and “small effect” in the display area 42 indicate the magnitude of the effect. Further, a length of the slide bar 43 of each item is set in accordance with the level of the importance degree. In the operation screen, as the importance degree is higher, a wider range is secured in which the value of the target feature amount can be changed. As described above, by displaying the items of the target feature amounts and the ranges of changeable values of the target feature amounts on the operation screen, the operation improvement assistance device 1 presents the items of the target feature amounts and the ranges of changeable values of the target feature amounts.

The operator moves each pointer 44 for each item of the feature amount by an operation of a mouse or the like. The operator changes the value of the target feature amount by moving the pointer 44. The simulation operation unit 18 changes the simulation result of the output data displayed on the operation screen in response to the change in the value of the target feature amount. After moving each pointer 44 in any ways, the operator performs an operation for determining a position of each pointer 44, to determine the changed value of each target feature amount. In FIG. 5, a graph of “improved prediction result” represents an example of a simulation result after the value of the target feature amount is changed. In this way, in accordance with the operation on the simulation operation unit 18, the operation improvement assistance device 1 changes the prediction result of the output data indicated by the simulation result, and presents the simulation result of the output data.

Next, an example of assistance by the operation improvement assistance device 1 according to the first embodiment will be described. A first example is an example of using a learned model generated by supervised learning. In the first example, the operation improvement assistance device 1 predicts a dimension of a processed product to be manufactured by a processing machine that is the FA device 2, and assists optimization of control parameters in a case where a prediction result does not satisfy a prescribed dimension. Thus, the operation improvement assistance device 1 assists in improving quality of the processed product, which is an outcome of the operation of the processing machine. Improving the quality of the processed product allows a production system to achieve a task of reducing a defect rate and increasing production efficiency.

The machine learning device 5 generates a learning model for predicting a dimension of a processed product from data on the processing machine, by using a data set including data on the processing machine in past processing and data on a dimension of a processed product in past processing. The data on the processing machine includes values of control parameters such as processing time, a current command value, a motor rotational speed, and a cooling water temperature. In addition, the data on the processing machine includes peripheral data such as a motor temperature, a facility temperature, and a machine number of the processing machine. The machine number is a number for identifying the processing machines. The dimension of the processed product is, for example, a numerical value in units of 0.1 mm. The machine learning device 5 generates a learned regression model through learning using a supervised learning algorithm with data on the processing machine as an input (x) and a dimension of the processed product as an output (y). The machine learning device 5 uses an algorithm such as multiple regression, a decision tree, and deep learning to generate the learned regression model. The generated learned regression model is stored in the learned model storage unit 32.

Next, regarding the first example, an operation of the operation improvement assistance device 1 in simulating a dimension of the processed product from data on the processing machine will be described. The simulation unit 22 inputs input data collected by the operation of the processing machine to the learned regression model, to predict a dimension of the processed product. Conventionally, namely in conventional art, it has only been known that a dimension of the processed product does not satisfy a prescribed dimension under present circumstances when a result of the prediction does not satisfy the prescribed dimension, and it has not been known what kind of improvement measures should be taken to correct the dimension of the processed product to the prescribed dimension.

In the first embodiment, the operation improvement assistance device 1 simulates output data predicted by changing a value of the target feature amount. The operation improvement assistance device 1 presents a simulation result determined as an improvement measure from among simulation results. Further, the operation improvement assistance device 1 changes a prediction result of the output data indicated in the simulation result, in accordance with the operation of changing the value of the target feature amount. By referring to the presentation by the operation improvement assistance device 1, the operator can easily consider an improvement measure for correcting the dimension of the processed product to the prescribed dimension.

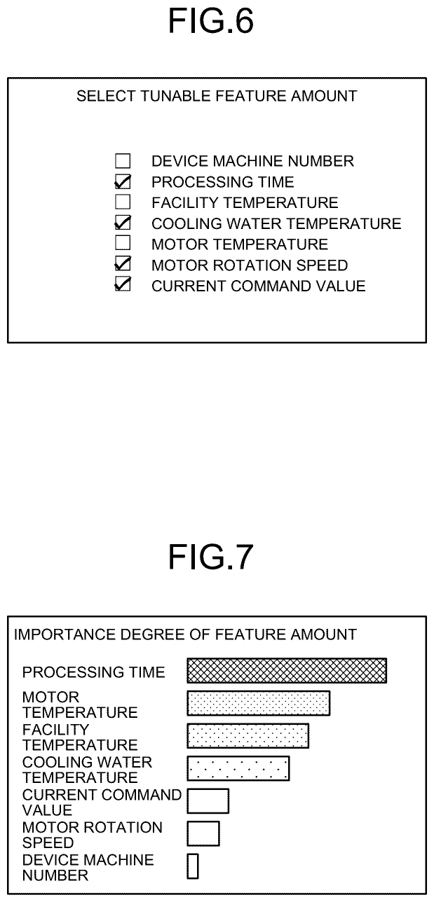

FIG. 6 is a view for explaining selection of a feature amount in the operation improvement assistance device 1 according to the first embodiment. FIG. 6 illustrates an example of a selection screen displayed by a function of the target feature amount input unit 15. The selection screen displays a message “select a tunable feature amount” and items of feature amounts as a selection target. In FIG. 6, each of “device machine number”, “processing time”, “facility temperature”, “cooling water temperature”, “motor temperature”, “motor rotation speed”, and “current command value” is an example of an item of a feature amount. The “device machine number” represents a machine number of the processing machine. In addition, a check box for selecting an item is displayed on the left of each item.

The target feature amount input unit 15 displays each item of all feature amounts whose values are included in the input data, as an option on the selection screen.

In the first example, as illustrated in FIG. 6, the “processing time”, the “cooling water temperature”, the “motor rotation speed”, and the “current command value”, which are control parameters, are selected by the operator. When the operator checks the check box by operating a mouse or the like, information on the feature amounts selected by the operator is inputted to the target feature amount input unit 15. Note that the selection method described here is an example, and is not limited to this method.

FIG. 7 is a view for explaining an importance degree acquired in order to select a target feature amount in the operation improvement assistance device 1 according to the first embodiment. In FIG. 7, for each item of the feature amount illustrated in FIG. 6, the importance degree of the feature amount is represented by a bar graph.

The target feature amount extraction unit 23 acquires information on the importance degree of each of the feature amounts, from the learned regression model. At the time of learning, information indicating the importance degree of the feature amount, such as a coefficient in linear regression or Gini impurity in a decision tree, is calculated. The learned regression model includes information indicating the importance degree of the feature amount. The target feature amount extraction unit 23 acquires information on the importance degree for each feature amount from the learned regression model. In the example illustrated in FIG. 7, the importance degree increases in the order of the “device machine number”, the “motor rotation speed”, the “current command value”, the “cooling water temperature”, the “facility temperature”, the “motor temperature”, and the “processing time”.

The target feature amount extraction unit 23 selects a feature amount that satisfies a condition regarding a level of the importance degree from among the feature amounts selected by the operator. Thus, the target feature amount extraction unit 23 extracts, as the target feature amount, a feature amount whose value can be changed and whose importance degree is high. The condition regarding the level of the importance degree is, for example, that a value representing the level of the importance degree is larger than a threshold value. A method for the target feature amount extraction unit 23 to extract the target feature amount according to the importance degree is not limited to the method based on comparison with a threshold value, and can be any method.

In the first example, the target feature amount extraction unit 23 extracts the “processing time”, the “cooling water temperature”, and the “current command value” as target feature amounts among the individual items of the feature amounts illustrated in FIGS. 6 and 7. The operation improvement assistance device 1 changes only a value of the target feature amount in the input data in simulation by the simulation unit 22, and records a change in a prediction value of the dimension of the processed product. The operation improvement assistance device 1 stores, as a simulation result, the changed value of the target feature amount and a prediction value changed in accordance with the change of the value of the target feature amount.

Next, regarding the first example, an operation of the operation improvement assistance device 1 in using a simulation result will be described. When the prediction value of the dimension of the processed product does not satisfy the prescribed dimension, the operator inputs a target value of the dimension of the processed product on the input screen illustrated in FIG. 4. When the target value is inputted, a simulation result determined by the improvement processing unit 21 is displayed on the operation screen illustrated in FIG. 5, as a simulation result that enables to achieve the target value of the output data or to obtain output data close to the target value. Since such a simulation result is a simulation result based on the learned regression model, it can be said that a value of the target feature amount corresponding to such a simulation result is an improvement measure recommended by artificial intelligence (AI) which is the machine learning device 5. Further, the value of the target feature amount corresponding to the simulation result can also be said to be an initial value before being changed by the operator. The operation improvement assistance device 1 displays a simulation result corresponding to the initial value recommended by the AI, on the operation screen.

When the operation of changing the value of the target feature amount is performed on the operation screen, the operation improvement assistance device 1 displays, on the operation screen, a simulation result changed in accordance with the change of the value of the target feature amount. The operator checks the simulation result according to the initial value recommended by the AI and the simulation result changed according to the change of the value of the target feature amount, on the operation screen. By checking the simulation result in which the dimension of the processed product is closer to the target value on the operation screen, the operator can obtain a control parameter suitable for bringing the dimension of the processed product closer to the target value.

For example, it is assumed that the initial values recommended by the AI are the “processing time” of seconds, the “cooling water temperature” of −5° C., and the “current command value” of 10 A. Since −5° C. is a temperature lower than a solidifying point of the cooling water, the “cooling water temperature” cannot be set to −5° C. Therefore, the operator sets the “cooling water temperature” to 5° C. and changes each value of the “processing time” and the “current command value”, and causes the operation improvement assistance device 1 to present the simulation result. When the operator determines that the dimension of the processed product can be brought close to the target value in a case where the “processing time” is 32 seconds and the “current command value” is 9 A among the presented simulation results, the operator determines a combination of the values of the target feature amounts as the “cooling water temperature” of 5° C., the “processing time” of 32 seconds, and the “current command value” of 9 A.

The operator can manually change the control parameters through a programmable indicator or the like by using the determined value of the target feature amount. Alternatively, by associating a data area of the control device 3 with the control parameter and directly connecting the operation improvement assistance device 1 to the control device 3, the operation improvement assistance device 1 can directly write the value of the target feature amount determined by the operation on the operation screen into the data area. The data area of the control device 3 is also referred to as a “device”. A feedback value outputted by the control feedback unit 16 is written in the data area of the control device 3.

It is also beneficial that the simulation result and the value of the target feature amount are recorded and used as appropriate. The operation improvement assistance device 1 can effectively use the feedback value and the simulation result, by outputting a report summarizing the feedback value and the simulation result. The operation improvement assistance device 1 may output the report in accordance with an instruction by the operator on the operation screen.

Next, a second example of assistance by the operation improvement assistance device 1 according to the first embodiment will be described. The second example is an example of using a learned model generated by unsupervised learning. In the first example, the operation improvement assistance device 1 performs anomaly prediction of a molding machine that is the FA device 2, and assists optimization of control parameters when an anomaly probability is equal to or greater than a certain probability. Thus, the operation improvement assistance device 1 assists in improving an operation status of the molding machine. Improving the operation status of the molding machine allows a production system to achieve a task of reducing a defect rate and increasing production efficiency.

The machine learning device 5 generates a learned model by using only molding-time data at normal time in the past. The molding-time data includes values of control parameters such as a mold temperature, an injection speed, an injection pressure, and a take-out time. In addition, the molding-time data includes peripheral data such as a resin temperature, a resin viscosity, an outside air temperature, a mold number, and a device machine number. The machine learning device 5 generates an anomaly detection model, which is a learned model, through learning using an unsupervised learning algorithm with data on a processing machine as an input (x). The machine learning device 5 uses an algorithm such as a Maharanobis Taguchi (MT) method or an auto encoder in generating the anomaly detection model. The generated anomaly detection model is stored in the learned model storage unit 32.

Next, regarding the second example, an operation of the operation improvement assistance device 1 when anomaly prediction of the molding machine is performed from the molding-time data will be described. The simulation unit 22 predicts an anomaly probability by inputting input data collected by operation of the molding machine, to the anomaly detection model. Conventionally, namely in conventional art, in a case where the anomaly probability is high, it has been only known that the anomaly probability is high under present circumstances, and it has not been known what kind of improvement measure should be taken to reduce the anomaly probability.

In the first embodiment, the operation improvement assistance device 1 simulates output data predicted by changing a value of the target feature amount. The operation improvement assistance device 1 presents a simulation result determined as an improvement measure from among simulation results. Further, the operation improvement assistance device 1 changes a prediction result of the output data indicated in the simulation result, in accordance with the operation of changing the value of the target feature amount. By referring to the presentation by the operation improvement assistance device 1, the operator can easily consider an improvement measure for reducing the anomaly probability.

In the second example, it is assumed that “mold temperature”, “injection speed”, “injection pressure”, and “take-out time”, which are control parameters, are selected by the operator as “tunable feature amount”.

The target feature amount extraction unit 23 acquires information on an importance degree of each feature amount from the anomaly detection model. At the time of learning, information indicating the importance degree of the feature amount is calculated, such as a contribution ratio in the MT method. The anomaly detection model includes information indicating the importance degree of the feature amount. The target feature amount extraction unit 23 acquires information on the importance degree of each feature amount from the anomaly detection model. In the second example, it is assumed that the importance degree increases in the order of the “mold number”, the “resin temperature”, the “mold temperature”, the “injection speed”, the “injection pressure”, the “outside air temperature”, and the “take-out time”.

The target feature amount extraction unit 23 selects a feature amount that satisfies a condition regarding a level of the importance degree from among the feature amounts selected by the operator. Thus, the target feature amount extraction unit 23 extracts, as the target feature amount, a feature amount whose value can be changed and whose importance degree is high. The condition regarding the level of the importance degree is, for example, that a value representing the level of the importance degree is larger than a threshold value. A method for the target feature amount extraction unit 23 to extract the target feature amount according to the importance degree is not limited to the method based on comparison with a threshold value, and can be any method.

In the second example, the target feature amount extraction unit 23 extracts the “mold temperature”, the “injection speed”, and the “injection pressure” as the target feature amounts. The operation improvement assistance device 1 changes only a value of the target feature amount in the input data in simulation by the simulation unit 22, and records a change in a prediction value of the anomaly probability. The operation improvement assistance device 1 stores, as a simulation result, the changed value of the target feature amount and a prediction value changed in accordance with the change of the value of the target feature amount.

Next, regarding the second example, an operation of the operation improvement assistance device 1 in using a simulation result will be described. When the anomaly probability is high, for example, when the anomaly probability is 50% or more, the operator sets a target value of the anomaly probability on the input screen illustrated in FIG. 4. The target value is set to, for example, a value of 20% or less. When the target value is inputted, a simulation result determined by the improvement processing unit 21 is displayed on the operation screen illustrated in FIG. 5, as a simulation result that enables to achieve the target value of the output data or obtain output data close to achievement of the target value. The operation improvement assistance device 1 displays a simulation result corresponding to the initial value recommended by the AI, on the operation screen.

When the operation of changing the value of the target feature amount is performed on the operation screen, the operation improvement assistance device 1 displays, on the operation screen, a simulation result changed in accordance with the change of the value of the target feature amount. The operator checks the simulation result according to the initial value recommended by the AI and the simulation result changed according to the change of the value of the target feature amount, on the operation screen. By checking the simulation result in which the anomaly probability is closer to the target value on the operation screen, the operator can obtain a control parameter suitable for achieving the target value of the anomaly probability.

For example, it is assumed that the initial values recommended by the AI are the “mold temperature” of 100° C., the “resin temperature” of 200° C., the “injection speed” of 10 mm/sec, and the “injection pressure” of 30 MPa. Since the “injection speed” is small and the “injection pressure” cannot be increased, the operator sets the “injection speed” to 20 mm/sec and changes the individual values of the “mold temperature”, the “resin temperature”, and the “injection pressure”, and causes the operation improvement assistance device 1 to present the simulation result. When the operator determines that the target value of the anomaly probability can be achieved when the “mold temperature” is 90° C., the “resin temperature” is 200° C., and the “injection pressure” is 30 MPa among the presented simulation results, the operator determines a combination of the values of the target feature amounts as the “mold temperature” of 90° C., the “resin temperature” of 200° C., and the “injection pressure” of 30 MPa.

The operator can manually change the control parameters through a programmable indicator or the like by using the determined value of the target feature amount. Alternatively, by associating a data area of the control device 3 with the control parameter and directly connecting the operation improvement assistance device 1 to the control device 3, the operation improvement assistance device 1 can directly write the value of the target feature amount determined by the operation on the operation screen into the data area of the control device 3. A feedback value outputted by the control feedback unit 16 is written in the data area of the control device 3.

It is also beneficial that the simulation result and the value of the target feature amount are recorded and used as appropriate. The operation improvement assistance device 1 can effectively use the feedback value and the simulation result, by outputting a report summarizing the feedback value and the simulation result. The operation improvement assistance device 1 may output the report in accordance with an instruction by the operator on the operation screen.

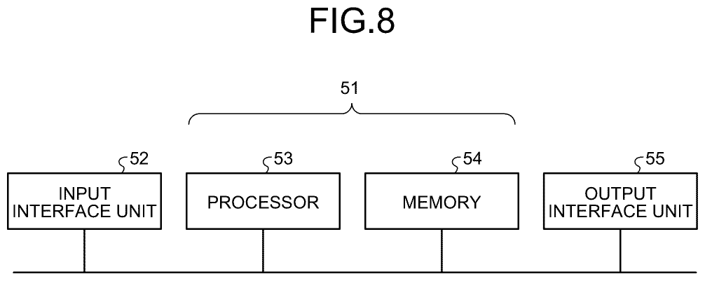

Next, a hardware configuration for implementing the operation improvement assistance device 1 according to the first embodiment will be described. FIG. 8 is a diagram illustrating a configuration example of hardware for implementing the operation improvement assistance device 1 according to the first embodiment. The operation improvement assistance device 1 is a computer system in which an operation improvement assistance program is installed. The operation improvement assistance program is a program for causing a computer to function as the operation improvement assistance device 1. The improvement processing unit 21, the simulation unit 22, and the target feature amount extraction unit 23, which are main parts of the operation improvement assistance device 1, are realized by processing circuitry 51 including a processor 53 and a memory 54.

An input interface unit 52 is a circuit that receives an input signal to be inputted to the operation improvement assistance device 1 from outside. An output interface unit 55 is a circuit that outputs a signal generated by the operation improvement assistance device 1 to outside. The user interface unit 10 is realized by the input interface unit 52 and the output interface unit 55. The input interface unit 52 is responsible for receiving data on the FA device 2 and receiving a learned model. The output interface unit 55 is responsible for transmitting a feedback value to outside and transmitting a report to outside. The input interface unit 52 includes a keyboard, a mouse, or the like that is an input device for the operator to input information. The output interface unit 55 includes a display device that displays an input screen and an operation screen. The display device is a display, a monitor, or the like.

The processor 53 is a central processing unit (CPU). The processor 53 may be an arithmetic device, a microprocessor, a microcomputer, or a digital signal processor (DSP). The memory 54 is, for example, a nonvolatile or volatile memory such as a random access memory (RAM), a read only memory (ROM), a flash memory, an erasable programmable read only memory (EPROM), or an electrically erasable programmable read only memory (EEPROM) (registered trademark).

The processor 53 executes the operation improvement assistance program. The operation improvement assistance program is a program in which processing for operating as the improvement processing unit 21, the simulation unit 22, and the target feature amount extraction unit 23, which are main parts of the operation improvement assistance device 1, is described. The operation improvement assistance program is stored in advance in the memory 54. The processor 53 reads and executes the operation improvement assistance program stored in the memory 54, to operate as the improvement processing unit 21, the simulation unit 22, and the target feature amount extraction unit 23. The memory 54 is also used as a temporary memory when the processor 53 executes various processes. The memory 54 includes a storage device that stores various types of information. The storage device is a hard disk drive (HDD) or a solid state drive (SSD). The simulation result storage unit 31, the learned model storage unit 32, and the input data storage unit 33 are realized by a storage device.

The operation improvement assistance program is stored in the memory 54 in advance, but is not limited thereto. The operation improvement assistance program may be provided to a user of the operation improvement assistance device 1 in a state of being written in a storage medium readable by the computer system, and installed in the memory 54 by the user. The storage medium may be a flexible disk which is a portable storage medium, or a flash memory which is a semiconductor memory. The operation improvement assistance program may be installed from another computer or server device to the memory 54 via a communication network.

According to the first embodiment, the operation improvement assistance device 1 extracts a target feature amount from a plurality of feature amounts whose values are included in input data. The operation improvement assistance device 1 simulates output data predicted by changing a value of the target feature amount, and presents a simulation result of the output data. The operation improvement assistance device 1 can present the simulation result obtained by changing the value of the target feature amount, as an improvement measure. Without determining, by the operator, a feature amount whose value is to be changed, the operator can consider a specific improvement measure from the content presented by the operation improvement assistance device 1. The operator can easily derive an effective improvement measure regardless of ability or experience of the operator.

The operation improvement assistance device 1 can use a learned model by supervised learning or unsupervised learning, to simulate the output data. The operation improvement assistance device 1 does not need to specify input data or a prediction target in advance for simulation according to a task, and a dedicated simulator does not need to be constructed. The operation improvement assistance device 1 can easily adjust a value of the input data in accordance with the task as compared with a case where a measure such as specification of data or construction of a simulator is required.

In addition, the operation improvement assistance device 1 presents a simulation result, an item of a target feature amount, and a range of a changeable value of the target feature amount, and receives an operation of changing the value of the target feature amount. The operator can intuitively understand a change in the output data when the value of the target feature amount is changed.

As described above, the operation improvement assistance device 1 has an effect of enabling to easily consider a measure for improving operation of a device. Note that the operation improvement assistance device 1 is not limited to operation of a factory, and may be applied to operation of a plant or the like in a field other than a production field.

The configuration described in the above embodiment is an example of the contents of the present disclosure. The configuration of the embodiment can be combined with another known technique. A part of the configuration of the embodiment can be omitted or changed without departing from the gist of the present disclosure.

### REFERENCE SIGNS LIST

1 operation improvement assistance device; 2 FA device; 3 control device; 4 data collection device; 5 machine learning device; 10 user interface unit; 11 input unit; 12 output unit; 13 operation unit; 14 target value input unit; 15 target feature amount input unit; 16 control feedback unit; 17 report output unit; 18 simulation operation unit; 20 data processing unit; 21 improvement processing unit; 22 simulation unit; 23 target feature amount extraction unit; 30 storage unit; 31 simulation result storage unit; 32 learned model storage unit; 33 input data storage unit; 41, 44 pointer; 42 display area; 43 slide bar; 51 processing circuitry; 52 input interface unit; 53 processor; 54 memory; 55 output interface unit.

1. A non-transitory computer readable storage medium storing an operation improvement assistance program for causing a computer to function as an operation improvement assistance device that assists improvement of an operation status of a device or improvement of an outcome by operation of the device, the operation improvement assistance program causing the computer to execute process procedures including:
predicting output data indicating the operation status or the outcome from input data including each value of a plurality of feature amounts related to operation of the device, the input data being data collected during operation of the device;
extracting a target feature amount that is a feature amount whose value is adjustable in prediction of the output data, from among the plurality of feature amounts;
simulating the predicted output data by changing a value of the target feature amount; and
presenting a simulation result of the output data.

2. The non-transitory computer readable storage medium storing the operation improvement assistance program according to claim 1, further causing the computer to execute:
presenting an item of the target feature amount and a range of a changeable value of the target feature amount, and receiving an operation of changing the value of the target feature amount in the range, wherein
in presenting the simulation result, a prediction result of the output data indicated by the simulation result is changed in accordance with the operation.

3. The non-transitory computer readable storage medium storing the operation improvement assistance program according to claim 1, wherein, in predicting the output data and simulating the output data, the output data is obtained by inputting the input data to a learned model generated by machine learning.

4. The non-transitory computer readable storage medium storing the operation improvement assistance program according to claim 3, further causing the computer to execute:
acquiring information on an importance degree of each of the plurality of feature amounts from the learned model, and extracting the target feature amount in accordance with the importance degree.

5. The non-transitory computer readable storage medium storing the operation improvement assistance program according to claim 4, further causing the computer to execute:
receiving an operation for selecting a feature amount whose value is changeable from the plurality of feature amounts; wherein
in extracting the target feature amount, the target feature amount is extracted from among selected feature amounts.

6. The non-transitory computer readable storage medium storing the operation improvement assistance program according to claim 1, wherein
in presenting a simulation result of the output data, the simulation result is displayed on a screen, and
a target value of the output data is inputted by an operation on the screen.

7. The non-transitory computer readable storage medium storing the operation improvement assistance program according to claim 1, further causing the computer to execute:
outputting the simulation result and a value of the target feature amount corresponding to the simulation result, to an outside of the operation improvement assistance device.

8. An operation improvement assistance device for assisting improvement of an operation status of a device or improvement of an outcome by operation of the device, the operation improvement assistance device comprising:
target feature amount extraction circuitry to extract a target feature amount that is a feature amount whose value is adjustable from among a plurality of feature amounts in order to simulate output data indicating the operation status or the outcome when the device is operated in accordance with input data, from the input data including each value of the plurality of feature amounts related to operation of the device, the input data being data collected during operation of the device;
simulation circuitry to obtain, by simulation, the output data corresponding to a changed value of the target feature amount; and
presentation circuitry to present a result of the simulation.

9. An operation improvement assistance method for assisting improvement of an operation status of a device or improvement of an outcome by operation of the device with an operation improvement assistance device, the operation improvement assistance method comprising:
predicting output data indicating the operation status or the outcome from input data including each value of a plurality of feature amounts related to operation of the device, the input data being data collected during operation of the device;
extracting a target feature amount that is a feature amount whose value is adjustable in prediction of the output data, from among the plurality of feature amounts;
simulating the predicted output data by changing a value of the target feature amount; and
presenting a simulation result of the output data.
